(19) United States
(12) Patent Application Publication
(10) Pub. No.: US 2016/0141443 A1
(43) Pub. Date: May 19, 2016

(54) RESTORATION METHOD OF SILICON-BASED PHOTOVOLTAIC SOLAR CELLS

(71) Applicant: COMMISSARIAT A L'ENERGIE ATOMIQUE ET AUX ENERGIES ALTERNATIVES, Paris (FR)

(72) Inventors: Miguel CASCANT-LOPEZ, Chambery (FR); Sébastien DUBOIS, Scionzier (FR)

(21) Appl. No.: 14/942,423

(22) Filed: Nov. 16, 2015

(30) Foreign Application Priority Data
Nov. 14, 2014 (FR) 14 61000

(51) Int. Cl. H01L 31/18; H01L 31/028

(52) U.S. Cl. CPC H01L 31/186; H01L 31/028

(57) ABSTRACT

The treatment method of a photovoltaic element comprises at least the following steps:
providing a silicon-based substrate (1) provided with at least one emitting area (1E) at the surface;
generating charge carriers in the substrate (1), while keeping the substrate (1) at a temperature within a temperature range comprised between 20° C. and 230° C. and preferably between 50° C. and 230° C.;
subjecting the substrate (1) to a magnetic field (B) during the charge carrier generation step, the magnetic field (B) having a component (Bc) substantially parallel to the interface (24) between the emitting area (1E) and the substrate (1).

### BACKGROUND OF THE INVENTION

The invention relates to a method and a device designed to reduce the degradation effects of the efficiency under illumination of silicon-based photovoltaic solar cells.

### STATE OF THE ART

Photovoltaic solar cells made from silicon substrates generally encounter a problem created by a degradation phenomenon of the photovoltaic efficiency under illumination. This phenomenon occurs during the first hours of illumination of the photovoltaic solar cells and is usually called LID effect (LID standing for Light-Induced Degradation).

The physical mechanisms at the origin of this degradation of the efficiency of photovoltaic solar cells under illumination do however remain not very well known. Furthermore, several scientific studies have shown that light elements present in silicon, in particular atoms of hydrogen (H), boron (B) and oxygen (O), generally participate in activation of defects when illumination of the photovoltaic solar cells is performed.

The LID effects can be attenuated by injecting charge carriers into the photovoltaic solar cells while at the same time heating said cells.

International Patent application WO 2007/107351 discloses a method aiming to achieve a stabilisation of the efficiency of photovoltaic solar cells when illumination is performed. In this document, the restoration method of the cells comprises a charge carrier injection step via an illumination or a polarisation of the photovoltaic solar cell, and a heating step of the substrate to a temperature comprised between 50° C. and 230° C.

This restoration method enabled the treated photovoltaic solar cell to recover stable performances under normal operating conditions.

However, the method described in the document referred to above requires long treatment times for a complete restoration of the photovoltaic cells. What is meant by treatment time is the period during which the solar cells are kept at a certain temperature when generation of charge carriers is performed in the cells. The treatment times can extend up to about 100 minutes, which makes this method incompatible with the usual industrial methods for fabrication of photovoltaic solar cells.

Furthermore, the restoration kinetics of the photovoltaic cells can be accelerated by increasing the quantity of charge carriers present in the treated photovoltaic solar cell. This increase can be achieved in particular by increasing the power of the incident lighting or the intensity of the electric current input to the cell. However, increasing the incident lighting power or the electric current input may lead to a very large increase of the temperature of the photovoltaic solar cell, limiting or eliminating the restoration effects of the photovoltaic solar cell.

### OBJECT OF THE INVENTION

A requirement exists to provide a method that is efficient, rapid, and easy to perform to restore silicon-based photovoltaic solar cells against degradation of the photovoltaic efficiency during illumination, while at the same time preserving the mechanical integrity and the photovoltaic performances of the treated cells.

This requirement tends to be satisfied and the above-mentioned shortcomings to be palliated by providing a treatment method of a photovoltaic element, comprising at least the following steps:
providing said element comprising a silicon-based substrate provided with at least one emitting area at the surface;
generating charge carriers in the substrate, while at the same time keeping the substrate at a temperature within a temperature range comprised between 20° C. and 230° C. and preferably between 50° C. and 230° C.;
subjecting the substrate to a magnetic field during the charge carrier generation step, the magnetic field having a component substantially parallel to the interface between the emitting area and the substrate.

According to another embodiment, the charge carrier generation step is obtained by illumination of the substrate. In preferential manner, the illumination is obtained using a light having a wavelength greater than or equal to 500 nm, and preferably greater than or equal to 800 nm, and lower than or equal to 1300 nm, and preferably lower than or equal to 1000 nm.

Advantageously, the magnetic field component has an intensity comprised between 10⁻⁴ T and 5*10⁻¹ T and advantageously greater than 10⁻³ T.

Furthermore, according to an advantageous embodiment:
the substrate is made from boron-doped silicon with a concentration comprised between 4.0×10¹⁴ at/cm⁻³ and 7.0×10¹⁶ at/cm⁻³; and
the restoration time t in seconds is greater than or equal to:

$${C}_{1} * {( ( {C}_{2} + \frac{1 - {C}_{2}}{1 + {( \frac{{B}_{c}}{0.0169} )}^{1.7352}} ) * I )}^{{C}_{3}} * {e}^{{C}_{4} / T}$$

where:
   T corresponds to the temperature in kelvin of the substrate;
   B_{c} corresponds to the intensity in Tesla of said magnetic field component;
   I corresponds to the irradiance in sun of the radiation projected onto the surface of the substrate;
   C₁ corresponds to a first constant comprised between 1.3×10⁻⁵ and 3.2×10⁻⁵ and preferably equal to 1.7×10⁻⁵;
C₂ corresponds to a second constant comprised between 1.00 and 32.0 and preferably equal to 4.32;
C₃ corresponds to a third constant comprised between −1.00 and −2.00 and preferably equal to −1.62;
C₄ corresponds to a fourth constant comprised between 6562 and 8523 and preferably equal to 7500.

Furthermore, if the substrate is made from boron-doped silicon with a concentration strictly greater than 7×10¹⁶ at/cm⁻³, the restoration time t in seconds is advantageously greater than or equal to:

$$( \frac{{C}_{1}^{′}}{( {C}_{2}^{′} + \frac{1 - {C}_{2}^{′}}{1 + {( \frac{{B}_{c}}{0.0169} )}^{1.7352}} ) * I} + {C}_{3}^{′} ) * {e}^{{C}_{4}^{′} / T}$$

where:
   T corresponds to the temperature in kelvin of the substrate;
   B_{c} corresponds to the intensity in Tesla of said magnetic field component;
   I corresponds to the irradiance in sun of the radiation projected onto the surface of the substrate;
   C′₁ corresponds to an additional first constant comprised between 1.2×10⁻⁸ and 1.9×10⁻⁸ and preferably equal to 1.51×10⁻⁸;
   C′₂ corresponds to an additional second constant comprised between 1.00 to 32.0 and preferably equal to 4.32;
   C′₃ corresponds to an additional third constant comprised between 2.5×10⁻⁸ and 4.0×10⁻⁸ and preferably equal to 4.0×10⁻⁸; and
   C′₄ corresponds to an additional fourth constant comprised between 6562 and 8523 and preferably equal to 7500.

According to one embodiment, the treatment method comprises a step of formation of electric contacts on the substrate, and the charge carrier generation step comprises application of an external electric voltage to the electric contacts.

Furthermore, to palliate the shortcomings set out in the foregoing, a device for performing treatment of a photovoltaic element is also provided comprising a silicon substrate provided with at least one emitting area, the device comprising:
means for generating charge carriers in the substrate;
heat treatment means configured to keep the substrate at a temperature comprised within a temperature range between 20° C. and 230° C. and preferably between 50° C. and 230° C.; and
means for applying a magnetic field configured so that the magnetic field has a component substantially parallel to the interface between the emitting area and the substrate.

According to one embodiment, the means for applying a magnetic field comprise permanent magnets and/or an electromagnet.

In preferential manner, the means for generating charge carriers in the photovoltaic element comprise a light source designed to illuminate the photovoltaic element.

Advantageously, the substrate is provided with electric contacts and the means for generating charge carriers in the substrate comprise means for applying an external electric voltage to the electric contacts.

### BRIEF DESCRIPTION OF THE DRAWINGS

Other advantages and features will become more clearly apparent from the following description of particular embodiments of the invention given for non-restrictive example purposes only and represented in the appended drawings, in which:

FIG. 1 schematically illustrates an embodiment of a photovoltaic element restoration device, in cross-section;

FIG. 2 schematically illustrates an example of a photovoltaic element in the presence of a magnetic field, in cross-section;

FIG. 3 represents the plot of the depthwise distribution of the concentration of the minority charge carriers in the substrate of the photovoltaic element for several mobility values of the electrons and of the holes;

FIG. 4 represents the plot of the variation of the mean concentration of the minority charge carriers within a substrate of a photovoltaic element, versus the intensity of the magnetic field, according to one embodiment;

FIGS. 5a and 5b represent plots of the depthwise distribution of the concentration of the minority charge carriers in the substrate of a photovoltaic element, respectively illuminated by two types of radiation and for different values of the intensity of the magnetic field applied to the substrate;

FIG. 6 represents the plot of the gain of the regeneration time of the photovoltaic element versus the intensity of the magnetic field, according to one embodiment.

### DESCRIPTION OF PREFERRED EMBODIMENTS OF INVENTION

A method for performing treatment, i.e. restoration, of a photovoltaic element, in particular a photovoltaic solar cell, is described in the following. Advantageously, the method treats the photovoltaic element against degradation of the efficiency under illumination, by generating charge carriers in said element. The method takes advantage of the effect of a transverse magnetic field to improve the kinetics and the efficiency of restoration of the treated elements.

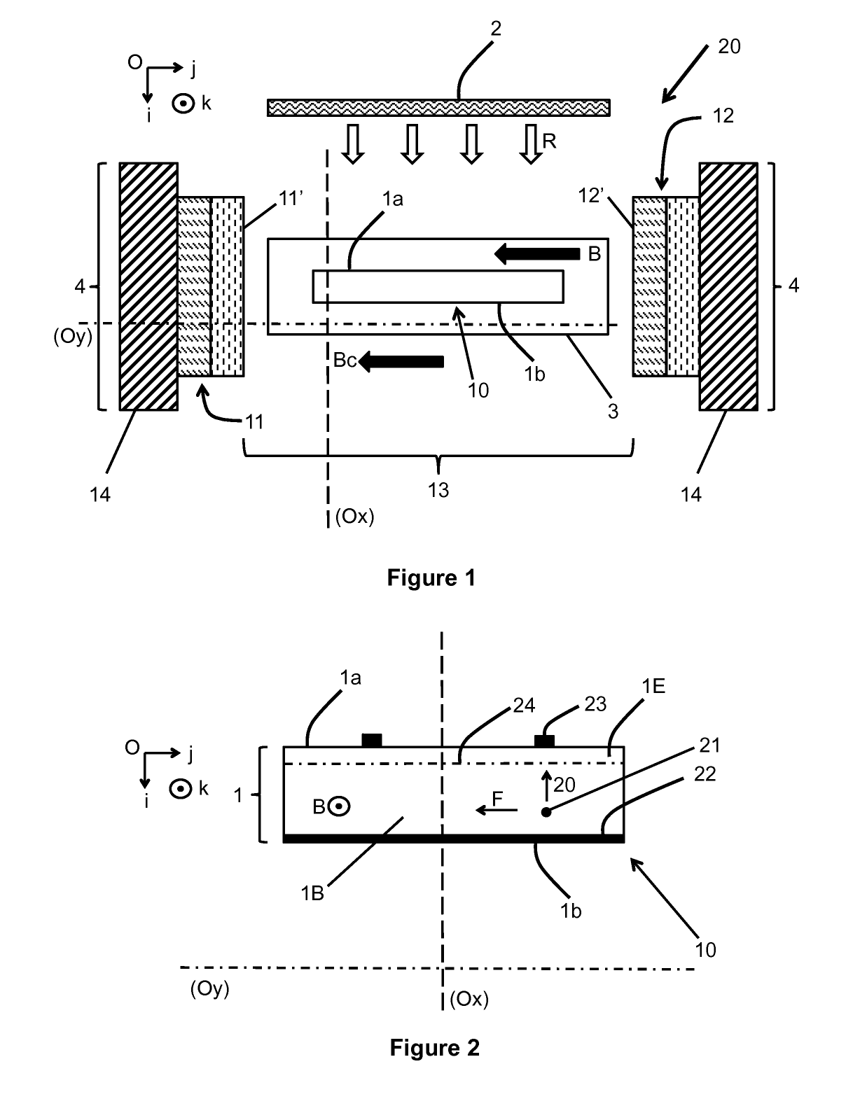

According to an embodiment illustrated in FIGS. 1 and 2, the method provides a photovoltaic element 10 comprising a silicon-based substrate 1. Substrate 1 is provided with a front surface 1a and a back surface 1b which are opposite and preferably substantially parallel to one another, and it can be formed by amorphous, monocrystalline or multicrystalline silicon. Substrate 1 is provided on its surface, at the surface 1a level, with at least one emitting area 1E. An interface 24 separates emitting area 1E from a base area 1B. Generally, the thickness of base area 1B is substantially larger than the thickness of emitting area 1E. In the following, reference will thus be made to the interface 24 between emitting area 1E and substrate 1.

Front surface 1a is designed to receive a light intensity to preferentially generate a resultant photocurrent. The generated photocurrent is generally proportional to the light intensity received on front surface 1a by substrate 1.

Photovoltaic element 10 is preferentially a solar cell of Al-BSF type. Photovoltaic element 10 can also be a photovoltaic cell of PERC or PERT type (PERC standing for Passivated Emitter and Rear Cell and PERT standing for Passivated Emitter, Rear Totally diffused cell). A solar cell of Al-BSF type comprises a passivation by field effect by means of a strong doping at the level of the back surface of the cell. The potential barrier induced by the difference of doping level between the base and the back surface tends to confine the minority carriers in the base and to move them away from the edge of the cell. This doping is generally performed by means of the contact on the aluminium-base back surface which forms an alloy with the silicon when annealing is performed. Under these conditions, a P+ doped area is formed on the whole of the back surface of the cell: this is then referred to as Back Surface Field (BSF).

Back surface 1b of substrate 1 can thus be covered by a layer of aluminium forming a contact connection for said photovoltaic element 10. The contact connection on the front surface is advantageously formed by an aluminium-based ohmic contact. Aluminium and silver in fact have a magnetic permeability close to 1, advantageously enabling distortion of the magnetic field lines within substrate 1 to be attenuated. Furthermore, silicon which constitutes the base material of photovoltaic element 10 also has a magnetic permeability close to 1.

The restoration method comprises a generation step of charge carriers in substrate 1 by heating the latter. Heating of the substrate is performed by keeping substrate 1 at a temperature comprised between 20° C. and 230° C.

Preferentially, the restoration method comprises an illumination step of photovoltaic element 10 configured to generate charge carriers in substrate 1. In other words, the charge carrier generation step is obtained by illumination of substrate 1.

According to the particular embodiment illustrated in FIG. 1, charge carrier generation is performed by means preferentially comprising a light source 2 illuminating photovoltaic element 10. The latter can be illuminated by different types of light sources. Furthermore, the charge carrier generation means can also constitute a heat source configured to both illuminate and heat substrate 1.

Advantageously, photovoltaic element 10 receives an illumination of more than 4000 W/m² during the restoration method.

Charge carrier generation can be performed by illumination and/or by injection of an electric current into substrate 1, in particular by an external potential difference source with respect to substrate 1.

As illustrated in FIG. 2, substrate 1 preferentially comprises electric contacts at the level of front surface 1a. The method in fact advantageously comprises formation of electric contacts 23 on substrate 1. The charge carrier generation step is obtained by application of an external electric voltage on contacts 23.

The means for generating charge carriers in substrate 1 thus further comprise means (not shown in the figures) for injecting an electric current into photovoltaic element 10. Preferentially, a current density of more than 30 mA/cm² is injected into element 10 to be treated.

To perform the heating step, substrate 1 is kept at a temperature value comprised within the 20° C.-230° C. temperature range, and preferably comprised within 50° C. and 230° C. temperature range. The temperature can be fixed or vary in the described range during generation of the charge carriers. The heating steps of solar cell 1 and of injection of the charge carriers into substrate 1 are steps performed simultaneously in order to enable the treated photovoltaic element 10 to recover stable performances under normal operating conditions.

In advantageous manner, the temperature of photovoltaic element 10 is kept at a target temperature value or within a target range comprised within the 120° C.-210° C. temperature range. Heating of photovoltaic element 10 can be performed by an external heat source or by charge carrier generating means 2, for example by halogen lamps.

Furthermore, the treatment method provides means 4 for applying a magnetic field B through the substrate 1. In other words, the treatment method comprises an applying step of a magnetic field B passing through photovoltaic element 10. Preferably, the treatment time of the photovoltaic element 10 is greater than 300 microseconds, and more preferentially greater than one second. What is meant by treatment time is the time during which the substrate 1 is kept at a target temperature value or within a target range comprised within the 20° C.-230° C. temperature range, while generating charge carriers and while applying the magnetic field B through the photovoltaic element 10.

As illustrated in FIG. 1, substrate 1 is subjected to a magnetic field B having a component Bc substantially parallel to interface 24 between emitting area 1E and substrate 1. Interface 24 represents the interface between the two opposite types of doping present in substrate 1, in other words the interface of the p/n junction forming base area 1B and emitting area 1E.

Generally, interface 24 is parallel to front surface 1a and back surface 1b. According to a particular embodiment, substrate 1 is subjected to a magnetic field B having a component Bc substantially perpendicular to an axis (Ox) passing through front surface 1a and back surface 1b.

What is meant by magnetic field component B is a component defined by an orthonormal coordinates system (O, i, j, k). Preferentially, surfaces 1a and 1b are substantially parallel, and the axis (Ox) is substantially perpendicular to surfaces 1a and 1b.

Photovoltaic element 10, in other words substrate 1, comprises a back contact 22, on back surface 1b, preferably made from aluminium, generating a back surface field BSF. Substrate 1 also comprises electric contacts 23 on front surface 1a. The movement of charge carriers 21 therefore follows a mean direction 20 substantially perpendicular to interface 24, in particular to surfaces 1a and 1b.

The magnetic field B applied to substrate 1 is configured so as not to be parallel to the mean direction 20 of the general movement of charge carriers 21. If not, the Lorentz force F generated would then be zero, and the magnetic field B would not have a notable influence on the concentration of minority charge carriers 21 in substrate 1.

Numerical simulations by the PC1D software developed by the University of New South Wales were performed to study the influence of a magnetic field on the minority charge carrier concentration in a photovoltaic element.

The simulations concerned solar cells of Al-BSF type. The Al-BSF cell studied comprises a P-doped silicon substrate 1 with a thickness of 200 μm and a majority charge carriers concentration at equilibrium of 6×10¹⁵ at/cm³. The numerical simulations were performed considering the solar cell in open circuit, and a front side illumination by a radiation having a spectrum of AM1.5G, in other words having an irradiance of 1000 W/m². Furthermore, the numerical simulations were performed considering the lifetime of the minority carriers in substrate 1 of photovoltaic element 10 to be equal to 10⁻³ s.

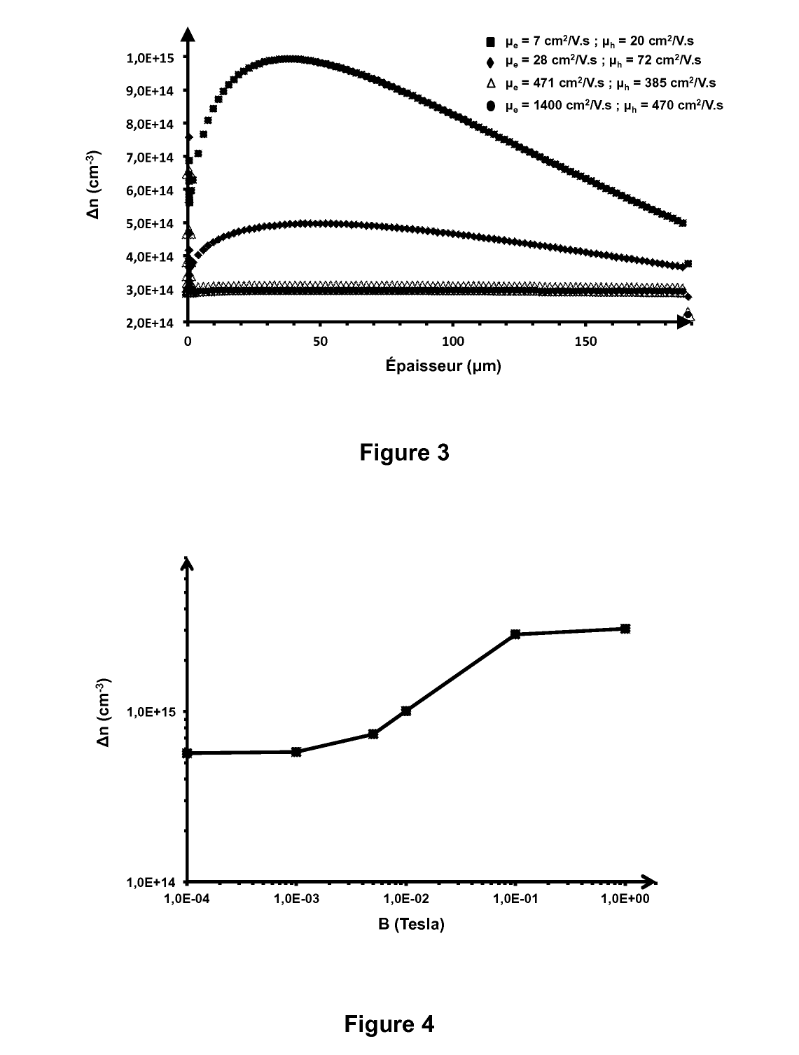

FIG. 3 represents the distribution of the minority charge carriers versus the depth of substrate 1, obtained by the numerical simulations for different mobility values of the electrons (μₑ) and of the holes (μₕ) in substrate 1, when different magnetic field values are applied. The results of the numerical simulations plotted in FIG. 3 clearly indicate that the concentration of minority carriers increases when the mobility of the carriers decreases. Furthermore, this increase is obtained under illumination conditions favourable to the phenomenon of degradation of the efficiency under illumination.

The results of the simulations show that application of a transverse magnetic field in substrate 1 leads to an increase of the concentration of minority carriers.

According to the advantageous embodiment of FIGS. 1 and 2, the magnetic field B is parallel to interface 24 between emitting area 1E and substrate 1, or base area 1B. Preferentially, the field B is configured so as to be perpendicular to the axis (Ox). In other words, the direction of the magnetic field B is in the plane (0, j, k). On account of this, a force parallel to interface 24 (i.e. to surfaces 1a and 1b of substrate 1) is applied to charge carriers 21 in movement. The amplitude of this generated force is then maximised, resulting in a large decrease of the charge carrier mobility. For a fixed intensity of the magnetic field B, such an orientation of the magnetic field advantageously generates an optimal increase of the quantity of minority charge carriers within substrate 1, thereby enabling an improvement of the restoration method kinetics.

FIG. 4 illustrates the variation of the mean concentration of the minority charge carriers Δn versus the intensity of the magnetic field applied to substrate 1. The studied cell is the same as that described in the foregoing, and the results of the simulations of which are plotted in FIG. 3. Furthermore, the calculations were performed considering that the restoration method was performed at a temperature of 127° C., and that the magnetic field B was perpendicular to the axis (Ox). The numerical simulations were performed considering a front side illumination by a radiation having a spectrum of AM1.5G, in other words having an irradiance of 1000 W/m².

According to a preferred embodiment, illumination is obtained using a light having a wavelength greater than or equal to 500 nm, and preferably greater than or equal to 800 nm, and less than or equal to 1300 nm, and preferably less than or equal to 1000 nm.

FIG. 4 shows that the mean concentration Δn increases with the increase of the intensity of the magnetic field B applied to substrate 1 in the treatment method. This increase is all the more striking when the intensity of the magnetic field B is greater than 0.001 T.

Advantageously, the treatment method is performed using a magnetic field B the component Bc of which has an intensity comprised between 10⁻⁴ T and 5×10⁻¹ T and advantageously greater than or equal to 0.001 T.

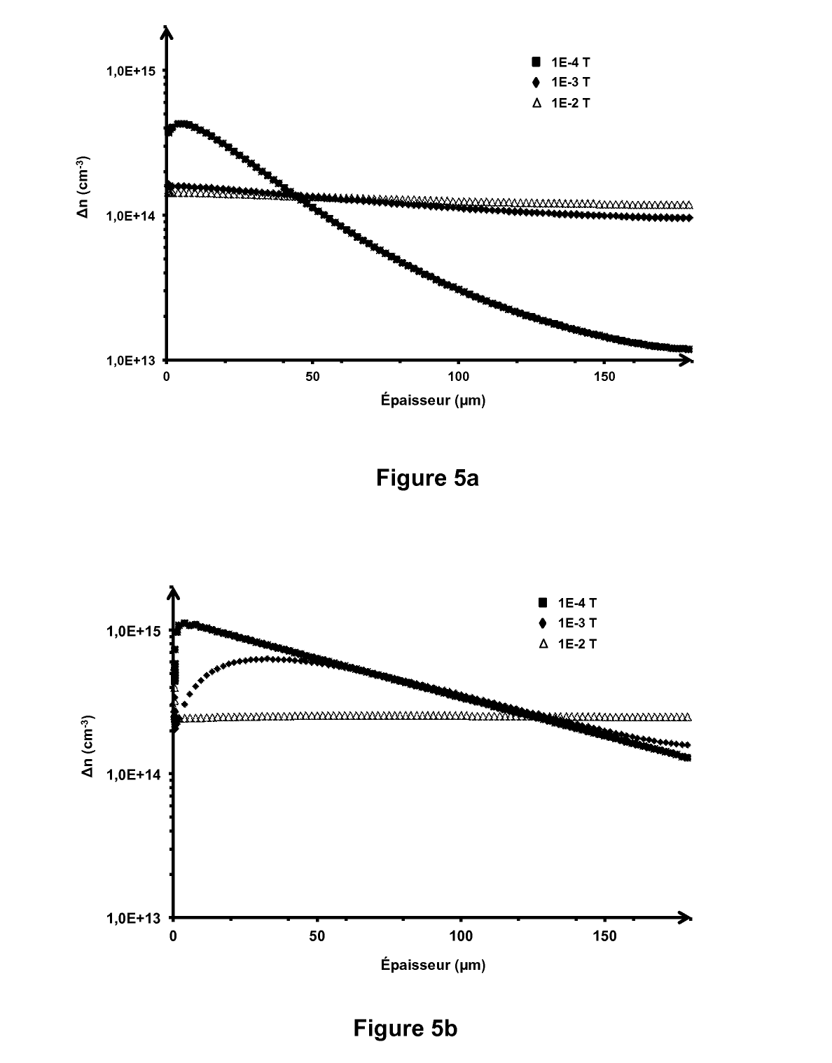

According to an advantageous embodiment, the illumination step of photovoltaic element 10 is performed by an infrared monochromatic radiation (R). Preferentially, the radiation (R) has a wavelength of about 1000 nm. FIGS. 5a and 5b illustrate the depthwise distribution (the origin being front surface 1a) of the mean concentration of minority charge carriers Δn. Each of the FIGS. 5a and 5b represents three distributions corresponding to three intensities of the magnetic field B perpendicular to the axis (Ox) equal to 10⁻⁴, 10⁻³ and 10⁻² T.

The calculations were performed for restoration methods of photovoltaic element 10 performed at a temperature of 25° C. and at an illumination intensity of 1000 W/m². FIG. 5a corresponds to the results obtained for a method using a front side illumination by a spectrum of AM1.5G type, whereas the results of FIG. 5b correspond to a front side illumination by an infrared monochromatic radiation having a wavelength equal to 1000 nm.

FIGS. 5a and 5b show the positive effects resulting from the use of a strong magnetic field in combination with an illumination by an infrared radiation. This combination does in fact advantageously enable a uniform distribution of the mean concentration of charge carriers Δn to be obtained. In addition to the uniformity of the distribution of the mean concentration, the use of an infrared monochromatic illumination enables a marked increase of the concentration Δn to be obtained, in particular at the level of emitting area 1E and of interface 24 of substrate 1 to be treated, in other words at the level of the p/n junction. This increase and this uniformity advantageously enable a faster and more uniform healing, depending on the depth, of photovoltaic element 10 to be treated.

Applying a transverse magnetic field in substrate 1 to be treated results in an increase of the mean concentration Δn. Advantageously, the method enables a very significant improvement of the restoration kinetics of photovoltaic elements from the effects of degradation of the efficiency under illumination.

Acceleration of the restoration kinetics results in a considerable decrease of the regeneration time of photovoltaic element 10. What is meant by regeneration time is the treatment time of photovoltaic element 10 necessary for the latter to recover stable performances under normal operating conditions.

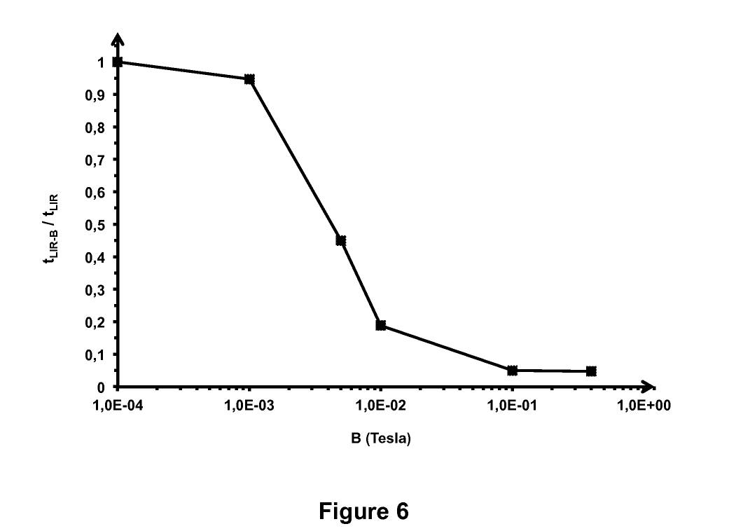

FIG. 6 illustrates the variation, versus the intensity of the magnetic field, of the ratio of the regeneration time of photovoltaic element 10 using a magnetic field t_{LIR-B} over the regeneration time of the photovoltaic element with a standard method t_{LIR}. What is meant by standard method is a method not using a magnetic field applied to the photovoltaic element. With the exception of applying a magnetic field, the two methods have the same implementation conditions. The calculations were performed considering that the restoration methods of photovoltaic element 10 were performed at a temperature of 127° C., and using an infrared monochromatic radiation with an irradiance of 1000 W/m².

FIG. 6 clearly shows that the use of a magnetic field applied to photovoltaic element 10 during the restoration method enables the regeneration time to be considerably reduced, in particular for intensities of the magnetic field of more than 5×10⁻³ T. For example, using a magnetic field having an intensity equal to 0.01 T, the regeneration time (t_{LIR-B}) corresponds to the regeneration time by the standard method (t_{LIR}) divided by about 5 for photovoltaic element 10 with a base formed by a substrate 1 presenting a lifetime in the volume of 10⁻³ s.

The restoration method using a transverse magnetic field applied to photovoltaic element 10 enables the regeneration time to be considerably reduced. The restoration method is thus advantageously compatible with industrial fabrication methods of photovoltaic solar cells.

Furthermore, by fixing the regeneration time, the restoration method using a magnetic field advantageously enables the illumination intensity, or irradiance, to be reduced. For example purposes, the use of a magnetic field applied to photovoltaic element 10 having an intensity of 0.01 T enables the illumination intensity necessary for regeneration to be divided by about 3 for the substrate presenting a lifetime in the volume of 10⁻³ s. It can thus be envisaged to use less intense illumination sources consuming less energy.

The different experiments and the different calculations made during the study of the treatment method using a transverse magnetic field enabled mathematical formulas to be established linking the time required for complete regeneration t_{LIR-B} according to the main parameters of the method. Indeed, mathematical formulas give the time t_{LIR-B} versus the temperature T in Kelvin of the photovoltaic element to the treated, of the intensity of the transverse magnetic field Bc in tesla applied to photovoltaic element 10 to be treated, and of the irradiance I in sun. The irradiance corresponds to the intensity of the radiation projected onto front surface 1a of substrate 1. In the international system of units, 1 sun corresponds to 1000 W/m². The mathematical formulas were established for P-doped silicon substrates based photovoltaic elements 10, and for transverse magnetic field intensities Bc comprised between 10⁻⁴ and 0.4 T.

Therefore, according to a preferred embodiment, photovoltaic element 10 is made from a boron-doped silicon substrate with a concentration comprised between 4×10¹⁴ at/cm³ and 7×10¹⁶ at/cm³. According to this embodiment, the treatment time t in seconds is advantageously greater than or equal to:

$${C}_{1} * {( ( {C}_{2} + \frac{1 - {C}_{2}}{1 + {( \frac{{B}_{c}}{0.0169} )}^{1.7352}} ) * I )}^{{C}_{3}} * {e}^{{C}_{4} / T} \qquad ( 1 )$$

where t designates the time during which the substrate 1 is kept at a target temperature value or within a target range comprised within the 20° C.-230° C. temperature range, while generating charge carriers and while applying the magnetic field B through the photovoltaic element 10, T corresponds to the temperature in kelvin of photovoltaic element 10, B_{c} corresponds to the intensity in tesla of said component Bc of the magnetic field B, and I corresponds to the irradiance in sun of the radiation projected on front surface 1a of substrate 1. Furthermore, in formula (1), C₁ corresponds to a first constant comprised between 1.3×10⁻⁵ and 3.2×10⁻⁵ and preferably equal to 1.7×10⁻⁵, C₂ corresponds to a second constant comprised between 1.00 and 32.0 and preferably equal to 4.32, C₃ corresponds to a third constant comprised between −1.00 and −2.00 and preferably equal to −1.62, and C₄ corresponds to a fourth constant comprised between 6562 and 8523 and preferably equal to 7500.

According to another preferred embodiment, photovoltaic element 10 is made from a boron-doped silicon substrate 1 with a concentration strictly greater than 7×10¹⁶ at/cm³. According to this embodiment, the treatment time t in seconds is greater than or equal to:

$$( \frac{{C}_{1}^{′}}{( {C}_{2}^{′} + \frac{1 - {C}_{2}^{′}}{1 + {( \frac{{B}_{c}}{0.0169} )}^{1.7352}} ) * I} + {C}_{3}^{′} ) * {e}^{{C}_{4}^{′} / T} \qquad ( 2 )$$

where t designates the time during which the substrate 1 is kept at a target temperature value or within a target range comprised within the 20° C.-230° C. temperature range, while generating charge carriers and while applying the magnetic field B through the photovoltaic element 10, T corresponds to the temperature in kelvin of photovoltaic element 10, B_{c} corresponds to the intensity in tesla of said component Bc of the magnetic field B, and I corresponds to the irradiance in sun of the radiation projected on front surface 1a of photovoltaic element 10. Furthermore, in formula (2), C′₁ corresponds to an additional first constant comprised between 1.20×10⁻⁸ and 1.90×10⁻⁸ and preferably equal to 1.51×10⁻⁸, C′₂ corresponds to an additional second constant comprised between 1.00 and 32.0 and preferably equal to 4.32, C′₃ corresponds to an additional third constant comprised between 2.5×10⁻⁸ and 4×10⁻⁸ and preferably equal to 3.7×10⁻⁸, and C′₄ corresponds to an additional fourth constant comprised between 6562 and 8523 and preferably equal to 7500.

Furthermore, a device designed to perform the treatment method described according to the different embodiments presented in the foregoing is also provided.

According to an embodiment illustrated in FIG. 1, restoration device 20 is configured to heal photovoltaic element 10. The latter comprises substrate 1 provided with front surface 1a and with back surface 1b opposite and preferably substantially parallel to one another. Front surface 1a is designed to receive a light intensity, or an irradiance. Substrate 1 comprises emitting area 1E on surface 1a, and base area 1B. Device 20 comprises means 2 for generating charge carriers in substrate 1. Preferably, device 20 comprises a first support (not represented in figures) designed to receive the substrate 1. The first support comprises preferably a main surface designed to be in contact with the back surface 1b of the substrate.

Charge carrier generating means 2 preferably comprise light source 2 illuminating the photovoltaic element 10 to be treated. Light source 2 can comprise monochromatic or multispectral lamps enabling an incident light beam to be produced having a wavelength preferably comprised between 300 and 1300 nm.

Light source 2 can just as well comprise halogen or xenon lamps. According to an embodiment, the light source is formed by xenon lamps performing a continuous illumination of photovoltaic element 10 to be treated with an irradiance of about 1000 W/m². Advantageously, light source 2 is configured to provide an intense illumination so that photovoltaic elements 10 receive an illumination of more than 5×10⁴ W/m².

Light source 2 can further comprise LEDs or a laser source, which advantageously generates an intense illumination. The use of a laser source or of LEDs advantageously enables the energy consumption to be reduced in comparison with other light sources.

Treatment device 20 also comprises heat treatment means 3 configured to keep substrate 1 at a temperature comprised within the 20° C.-230° C. temperature range, and preferably within the 50° C.-230° C. temperature range. Heat treatment means 3 can comprise a heat source. Furthermore, charge carrier generating means 2 can also form heat treatment means 3. For example, halogen lamps can illuminate solar cell 1 at the same time as they heat it.

As illustrated in FIG. 1, control of the temperature of substrate 1 is preferably performed by a chamber 3 configured to keep the temperature of substrate 1 at a target temperature value or within a target temperature range. Chamber 3 can be a conventional furnace equipped with temperature sensors configured to measure the temperature of substrate 1. The furnace can also comprise a temperature regulation device of photovoltaic element 10. The regulation device is connected to a control circuit configured to control the temperature of the furnace and the regulation device according to the temperature of photovoltaic element 10.

Furthermore, control means 3 of the temperature of substrate 1 are configured so that photovoltaic element 10 is illuminated. For example, chamber 3 for maintaining the temperature of photovoltaic element 10 can comprise light source 2.

Chamber 3 preferably comprises a wall transparent to the radiation emitted by light source 2. The transparent wall is placed between light source 2 and front surface 1a of photovoltaic element 10 so as to let the radiation emitted by light source 2 pass, thereby illuminating front surface 1a of substrate 1.

The device further comprises applying means 4 of a magnetic field B configured so that the magnetic field B has a component Bc substantially parallel to interface 24 between emitting area 1E and substrate 1. Preferably, component Bc is perpendicular to an axis (Ox) passing through front surface 1a and back surface 1b.

According to an embodiment, applying means 4 of a magnetic field B comprise two permanent magnets 11 and 12 separated by an air-gap 13. Magnets 11 and 12 are mounted on a support 14 so that they are arranged facing one another. Magnet 11 comprises a surface 11′ arranged facing a surface 12′ of magnet 12. Magnets 11 and 12 are configured in such a way that surfaces 11′ and 12′ facing one another have opposite magnetic poles (N and S).

Magnets 11 and 12 are configured to create the transverse magnetic field B flowing through the space of air-gap 13. According to the architecture and the composition of photovoltaic element 10 or substrate 1, and of chamber 3, magnets 11 and 12 are arranged so as to create the magnetic field B having a component Bc substantially parallel to interface 24. Preferentially, interface 24 is parallel to surfaces 1a and 1b, and magnets 11 and 12 are configured and arranged in such a way that the magnetic field B created has a direction parallel to surfaces 1a and 1b.

Air-gap 13 is further configured to comprise photovoltaic element 10 to be treated. In other words, air-gap 13 is configured to accommodate chamber 3 comprising photovoltaic element 10. In preferential manner, device 20 comprises fixing means (not shown in the figure) of elements located in air-gap 13, in particularly fixing means of photovoltaic element 10. Fixing of the elements arranged in air-gap 13 prevents distortion of the magnetic field lines created in substrate 1. This enables a stable and homogenous treatment method to be had in substrate 1.

Preferentially, chamber 3 is made from materials having magnetic permeabilities close to 1. For example, chamber 3 can be made from aluminium. A material having a magnetic permeability close to 1 does in fact advantageously enable distortion of the magnetic field lines within substrate 1 to be attenuated. Magnets 11 and 12 thus create a homogeneous flux of magnetic field B in substrate 1 arranged in air-gap 13.

According to an embodiment, the two magnets 11 and 12 are of Nb type having a residual flux density of 1320 mT, and a coercitive magnetic field greater than 11 Oesterd. Magnets 11 and 12 are cylindrical bars having a circular cross-section with a radius of 100 mm. Cylindrical bars 11 and 12 have a thickness of 30 mm. What is meant by thickness is the dimension of magnets 11 and 12 along the axis (Oy). Magnets 11 and 12 are separated by a distance of about 150 mm. In other words, the size of air-gap 13 along the axis (Oy) is about 150 mm. Air-gap 13 can thus accommodate a commercial photovoltaic element arranged in such a way that surfaces 1a and 1b are parallel to the axis (Oy).

By using mathematical formulas known from the state of the art, the flux density, in other words the intensity of the magnetic field B along the axis (Oy) of air-gap 13, can be calculated from the characteristics and dimensions of magnets 11 and 12.

Thus, according to the embodiment described in the foregoing, magnets 11 and 12 enable a transverse magnetic field B having a direction parallel to the axis (Oy) and an intensity comprised between 250 mT and 400 mT to be created in air-gap 13.

According to an embodiment not illustrated in the figures, applying means 4 of the magnetic field B comprise an electromagnet. The magnetic field B can in fact be generated by the permanent magnets 11 and 12 and/or by an electromagnet comprising for example an electromagnetic coil. The final distribution of the magnetic field lines depends on the final configuration of the installation of magnets 11 and 12 and/or of the electromagnet. This distribution can be non-uniform thereby generating an irregularity of the intensity of the magnetic field B in substrate 1 to be treated.

In all cases, the installation has to be dimensioned and applying means 4 of the magnetic field B have to be arranged so as to guarantee a minimum value of the intensity of the magnetic field applied to a photovoltaic element 10 to be treated, and a component Bc substantially parallel to interface 24, and preferentially perpendicular to the axis (Ox) passing through front surface 1a and back surface 1b.

According to another embodiment, means 2 for generating charge carriers in substrate 1 comprise means for injecting an electric current into substrate 1. The current injecting means are external to photovoltaic element 10.

The means for injecting an electric current into substrate 1 can form a complement to a light source illuminating photovoltaic element 10. Furthermore, the means for injecting current can also replace the light source configured to generate minority charge carriers within photovoltaic element 10 to be treated.

The injecting means can comprise probes connected to a potential difference generator. Said probes are configured to be in contact with contacts 23 of photovoltaic element 10 in order to inject an electric current into the latter.

The potential difference generator is configured to impose a larger potential difference than the voltage of the photovoltaic element in open circuit on the terminals of photovoltaic element 10. Preferentially, the potential difference generator is configured to impose a potential difference typically greater than 0.6 or 0.75 V on photovoltaic element 10. Furthermore, the current to be injected into photovoltaic element 10 depends on the characteristics of the latter and on the carrier concentration sought to input.

According to another embodiment, treatment device 20 is configured to treat several photovoltaic elements simultaneously. Chamber 3 is thus configured to accommodate several photovoltaic elements arranged in air-gap 13.

Advantageously, the photovoltaic elements are arranged in parallel manner to the axis (Oy) so as to be one above the other so that the axis (Ox) passes through all the stacked photovoltaic elements. According to this embodiment, the generating charge carriers means 2 are advantageously formed by an electric current injecting means. In preferential manner, the photovoltaic elements to be treated are electrically connected in series.

1. A treatment method of a photovoltaic element against Light-Induced Degradation, comprising at least the following steps:
providing said photovoltaic element comprising a silicon-based substrate provided with at least one emitting area at a surface of said substrate;
generating charge carriers in the substrate, while at the same time keeping the substrate at a temperature within a temperature range comprised between 20° C. and 230° C., and subjecting the substrate to a magnetic field having a component substantially parallel to an interface between the at least one emitting area and the substrate, said component of the magnetic field having an intensity comprised between 10⁻⁴ T and 5*10⁻¹ T.

2. The method according to claim 1, wherein charge carrier generation is obtained by illumination of the substrate.

3. The method according to claim 2, wherein illumination is obtained using a light having a wavelength greater than or equal to 500 nm.

4. The treatment method according to claim 1, wherein:
the substrate is made from boron-doped silicon with a concentration comprised between 4.0*10¹⁴ at/cm⁻³ and 7.0*10¹⁶ at/cm⁻³; and
a treatment time of the photovoltaic element, in seconds, is greater than or equal to:
$${C}_{1} * {( ( {C}_{2} + \frac{1 - {C}_{2}}{1 + {( \frac{{B}_{c}}{0.0169} )}^{1.7352}} ) * I )}^{{C}_{3}} * {e}^{{C}_{4} / T}$$
where:
T corresponds to the temperature in kelvin of the substrate;
B_{c} corresponds to the intensity in Tesla of said component of the magnetic field;
I corresponds to the irradiance in sun of the radiation projected onto the surface of the substrate;
C₁ corresponds to a first constant comprised between 1.3*10⁻⁵ and 3.2*10⁻⁵ and preferably equal to 1.7*10⁻⁵;
C₂ corresponds to a second constant comprised between 1.00 and 32.0 and preferably equal to 4.32;
C₃ corresponds to a third constant comprised between −1.00 and −2.00 and preferably equal to −1.62;
C₄ corresponds to a fourth constant comprised between 6562 and 8523 and preferably equal to 7500.

5. The treatment method according to claim 1, wherein:
the substrate is made from boron-doped silicon with a concentration strictly greater than 7*10¹⁶ at/cm⁻³; and
a treatment time of the photovoltaic element, in seconds, is greater than or equal to:
$$( \frac{{C}_{1}^{′}}{( {C}_{2}^{′} + \frac{1 - {C}_{2}^{′}}{1 + {( \frac{{B}_{c}}{0.0169} )}^{1.7352}} ) * I} + {C}_{3}^{′} ) * {e}^{{C}_{4}^{′} / T}$$
where:
T corresponds to the temperature in kelvin of the substrate;
B_{c} corresponds to the intensity in Tesla of said component of the magnetic field;
I corresponds to the irradiance in sun of the radiation projected onto the surface of the substrate;
C′₁ corresponds to an additional first constant comprised between 1.2*10⁻⁸ and 1.9*10⁻⁸ and preferably equal to 1.51*10⁻⁸;
C′₂ corresponds to an additional second constant comprised between 1.00 to 32.0 and preferably equal to 4.32;
C′₃ corresponds to an additional third constant comprised between 2.5*10⁻⁸ and 4.0*10⁻⁸ and preferably equal to 4.0*10⁻⁸; and
C′₄ corresponds to an additional fourth constant comprised between 6562 and 8523 and preferably equal to 7500.

6. The method according to claim 1, comprising forming electric contacts on the substrate, and wherein charge carrier generation comprises application of an external electric voltage to the electric contacts.

7. A treatment device of a photovoltaic element against Light-Induced Degradation, the photovoltaic element comprising a silicon substrate provided with at least one emitting area, comprising:
a charge carriers generator for creating charge carriers in the substrate;
a heat source configured to keep a volume, configured to house the photovoltaic element, at a temperature comprised within the temperature range between 20° C. and 230° C.; and
a magnetic field generator for applying a magnetic field flowing through an air-gap comprising said volume, the magnetic field generator being configured so that the magnetic field has a component substantially parallel to an interface between said at least one emitting area and the substrate, and so that the component of the magnetic field has an intensity comprised between 10⁻⁴ T and 5*10⁻¹ T.

8. The device according to claim 7, wherein the magnetic field generator comprises permanent magnets.

9. The device according to claim 7, wherein the magnetic field generator comprises an electromagnet.

10. The device according to claim 7, wherein the charge carriers generator comprises a light source designed to illuminate said volume.

11. The device according to claim 7, wherein the substrate is provided with electric contacts and wherein the charge carriers generator comprises potential difference generator for applying an external electric voltage to the electric contacts.

12. The method according to claim 3, comprising forming electric contacts on the substrate, and wherein charge carrier generation comprises application of an external electric voltage to the electric contacts.

13. The method according to claim 1, wherein said component of the magnetic field has an intensity greater than 10⁻³ T.

14. The method according to claim 2, wherein illumination is obtained using a light having a wavelength comprised between 800 nm and 1300 nm.

15. The method according to claim 2, wherein illumination is obtained using a light having a wavelength comprised between 800 nm and 1000 nm.

16. A treatment device of a photovoltaic element against Light-Induced Degradation, the photovoltaic element comprising a silicon substrate provided with at least one emitting area, comprising:
a charge carriers generator for creating charge carriers in the substrate;
a heat source configured to keep a volume at a temperature comprised within the temperature range between 20° C. and 230° C., the volume being configured to house a first support comprising a main surface designed so as to receive the photovoltaic element; and
a magnetic field generator for applying a magnetic field flowing through an air-gap comprising said volume, the magnetic field generator being configured so that the magnetic field has a component substantially parallel to an interface between said at least one emitting area and the substrate, and so that the component of the magnetic field has an intensity comprised between 10-4 T and 5*10-1 T.
